(19) United States
(12) Patent Application Publication
(10) Pub. No.: US 2022/0285525 A1
(43) Pub. Date: Sep. 8, 2022

(54) METHOD FOR MANUFACTURING STRUCTURE, AND STRUCTURE

(71) Applicants: SCIOCS COMPANY LIMITED, Hitachi-shi, Ibaraki (JP); SUMITOMO CHEMICAL COMPANY, LIMITED, Tokyo (JP)

(72) Inventors: Fumimasa HORIKIRI, Hitachi-shi (JP); Noboru FUKUHARA, Hitachi-shi (JP)

(73) Assignees: SCIOCS COMPANY LIMITED, Hitachi-shi, Ibaraki (JP); SUMITOMO CHEMICAL COMPANY, LIMITED, Tokyo (JP)

(21) Appl. No.: 17/630,413

(22) PCT Filed: Jul. 6, 2020
(86) PCT No.: PCT/JP2020/026454

§ 371 Date: Jan. 26, 2022

(30) Foreign Application Priority Data
Jul. 30, 2019 (JP) 2019-140027

(51) Int. Cl. H01L 29/66; H01L 21/306; H01L 29/40; H01L 21/308; H01L 29/778

(52) U.S. Cl. CPC H01L 29/66462; H01L 21/30612; H01L 21/30625; H01L 29/401; H01L 21/3081; H01L 29/778

(57) ABSTRACT

There is provided a method for manufacturing a structure, including: forming a recess portion by performing a first etching to a surface of a member composed of Group III nitride; and flattening a bottom of the recess portion by performing a second etching to the bottom, wherein in forming the recess portion, a flat portion and a protruding portion are formed on the bottom of the recess portion, the protruding portion being raised with respect to the flat portion because it is less likely to be etched by the first etching than the flat portion, and in flattening the bottom, by etching the protruding portion by the second etching, the protruding portion is lowered.

### TECHNICAL FIELD

The present invention relates to a method for manufacturing a structure, and a structure.

### DESCRIPTION OF RELATED ART

Group III nitrides such as gallium nitride (GaN) are used as materials for manufacturing semiconductor devices such as light emitting devices and transistors.

Photoelectrochemical (PEC) etching has been proposed as an etching technique for forming various structures on Group III nitrides such as GaN (see, for example, Non-Patent document 1). PEC etching is a wet etching with less damage than general dry etching, and the PEC etching is preferable in the point that an apparatus is simpler than special dry etching with less damage such as neutral particle beam etching (see, for example, Non-Patent Document 2) and atomic layer etching (see, for example, Non-Patent Document 3).

When manufacturing a semiconductor device composed of Group III nitride using PEC etching, the flatness of a bottom of a recess portion formed by PEC etching affects the characteristics of the semiconductor device.

### PRIOR ART DOCUMENT

### Non-Patent Document

[Non-patent document 1] J. Murata et al., “Photo-electrochemical etching of free-standing GaN wafer surfaces grown by hydride vapor phase epitaxy”, Electrochimica Acta 171 (2015) 89-95

[Non-Patent Document 2] S. Samukawa, JJAP, 45(2006)2395.

[Non-Patent Document 3] T. Faraz, ECS J. Solid Stat. Scie. & Technol., 4, N5023 (2015).

### SUMMARY OF THE INVENTION

### Problem to be Solved by the Invention

An object of the present invention is to provide a technique for improving a flatness of a bottom of a recess portion formed by PEC etching.

### Means for Solving the Problem

According to an aspect of the present invention, there is provided a method for manufacturing a structure, including:

forming a recess portion by performing a first etching to a surface of a member composed of Group III nitride; and

flattening a bottom of the recess portion by performing a second etching to the bottom,

wherein in forming the recess portion, a flat portion and a protruding portion are formed on the bottom of the recess portion, the protruding portion being raised with respect to the flat portion because it is less likely to be etched by the first etching than the flat portion, and

in flattening the bottom, by etching the protruding portion by the second etching, the protruding portion is lowered.

According to other aspect of the present invention, there is provided a structure having a member, which is composed of Group III nitride and has a recess portion,

in which a maximum height at a position corresponding to a dislocation of the Group III nitride constituting the member is 2 nm or less, which is measured by observing a 1000 nm square region on the bottom of the recess portion using AFM, and

arithmetic mean roughness (Ra) of the bottom measured by observing using the AFM is 0.4 nm or less.

### Advantage of the Invention

A technique is provided for improving the flatness of the bottom of the recess portion formed by PEC etching.

### BRIEF DESCRIPTION OF THE DRAWINGS

FIG. 1(a) is a schematic cross-sectional view illustrating HEMT according to an embodiment of the present invention, and FIG. 1(b) is a schematic cross-sectional view illustrating a wafer used as a material for the HEMT according to an embodiment.

FIG. 2(a) is a schematic cross-sectional view illustrating a PEC object according to an embodiment, and FIG. 2(b) is a schematic cross-sectional view of a PEC etching apparatus, illustrating a recess forming step.

FIG. 3(a) is a schematic cross-sectional view illustrating a flattening object according to an embodiment, and FIG. 3(b) is a schematic cross-sectional view of a flattening etching apparatus, illustrating a flattening step.

FIG. 4(a) is a graph showing a relationship between an etching time and an etching depth of PEC etching according to an experimental example, and FIG. 4(b) is an AFM image of an epi layer surface according to the experimental example.

FIG. 5(a) is an AFM image of an unflattened bottom according to the experimental example, and FIG. 5(b) is an AFM image of a flattened bottom according to the experimental example.

FIG. 6(a) is a schematic cross-sectional view illustrating a flattening object of a second modified example, and FIG. 6(b) is a schematic cross-sectional view of a flattening etching apparatus, illustrating a flattening step.

FIG. 7 is a schematic cross-sectional view of a flattening etching apparatus according to a third modified example.

FIG. 8 is a schematic cross-sectional view illustrating a PEC object according to another embodiment.

### DETAILED DESCRIPTION OF THE INVENTION

### Embodiment

A method for manufacturing a structure 150 according to an embodiment of the present invention will be described. A high electron mobility transistor (HEMT) is exemplified as the structure 150. Hereinafter, the structure 150 is also referred to as a HEMT 150.

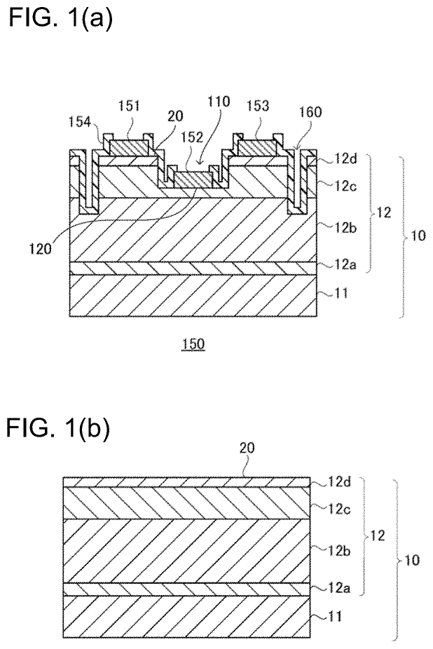

First, a structure of the HEMT 150 and a wafer 10 used as a material of the HEMT 150 will be described. FIG. 1(a) is a schematic cross-sectional view illustrating the HEMT 150, and FIG. 1(b) is a schematic cross-sectional view illustrating the wafer 10.

The wafer 10 has a substrate 11 and a Group III nitride layer 12 (hereinafter, also referred to as an epi layer 12) formed (epitaxially grown) on the substrate 11. For example, a semi-insulating silicon carbide (SiC) substrate is used as the substrate 11. Here, “semi-insulating” means, for example, a state in which a specific resistance is 10⁵ Ωcm or more. In contrast, for example, a state in which the specific resistance is less than 10⁵ Ωcm is called “conductive”. A substrate in which a thick semi-insulating epi layer is formed on a conductive substrate (for example, a substrate in which a carbon (C)-doped semi-insulating GaN layer having a thickness of 10 μm is formed on an n-type conductive gallium nitride (GaN) substrate), may be used as the substrate 11.

As the epi layer 12 when using the SiC substrate, for example, a laminated structure of a nucleation layer 12a made of aluminum nitride (AlN), a thick channel layer 12b made of gallium nitride (GaN), a barrier layer 12c made of gallium nitride (AlGaN), and a cap layer 12d made of GaN is used. In the lamination of the channel layer 12b and the barrier layer 12c, a two-dimensional electron gas (2DEG) to be a channel of the HEMT150, is generated in the vicinity of an upper surface of the channel layer 12b.

The substrate 11 is not limited to the SiC substrate, and other substrates (sapphire substrate, silicon (Si) substrate, (semi-insulating) GaN substrate, etc.) may be used. The laminated structure of the epi layer 12 may be appropriately selected depending on the type of the substrate 11, the characteristics of the HEMT 150 to be obtained, and the like.

A surface 20 of the epi layer 12 is composed of a c-plane of the Group III nitride constituting the epi layer 12. Here, the phrase “composed of the c-plane” means that a lowest index crystal plane closest to the surface 20 is the c-plane of the Group III nitride crystal constituting the epi layer 12. The Group III nitride constituting the epi layer 12 has dislocations (through dislocations), and the dislocations are distributed at a predetermined density in the surface 20.

In the HEMT150 of the present embodiment, a gate electrode 152 is formed on a bottom 120 of the recess portion (recess) 110 formed on the surface (upper surface) 20 of the epi layer 12. The bottom 120 of the recess portion 110 is arranged within a thickness range of the barrier layer 12c, and a thickness of the barrier layer 12c under the recess portion 110 (the thickness from the upper surface of the channel layer 12b to the bottom 12 of the recess portion 110) may be set to a predetermined thickness so that a threshold gate voltage of the HEMT 150 becomes a predetermined value. The source electrode 151 and the drain electrode 153 are formed on the surface 20 of the epi layer 12. A protective film 154 is formed so as to have an opening on the upper surface of the source electrode 151, the gate electrode 152, and the drain electrode 153.

The gate electrode 152 is formed, for example, by a Ni/Au layer in which a gold (Au) layer is laminated on a nickel (Ni) layer. Each of the source electrode 151 and the drain electrode 153 is formed by, for example, a Ti/Al/Au layer in which an Al layer is laminated on a titanium (Ti) layer and an Au layer is further laminated on the Al layer.

The HEMT 150 has an element separation groove 160 that separates adjacent elements. The element separation groove 160 is provided so that its bottom is arranged at a position deeper than the upper surface of the channel layer 12b, that is, so that 2DEG is divided by the element separation groove 160 between adjacent elements.

Next, a method for manufacturing the HEMT150 will be described. The method for manufacturing the HEMT150 according to the present embodiment includes: forming a recess portion 110 by performing a first etching to the surface 20 of the epi layer 12 (a member composed of the Group III nitride) (hereinafter, also referred to as a recess forming step); and flattening the bottom 120 by performing a second etching to the bottom 120 of the recess portion 110 (hereinafter, also referred to as a flattening step).

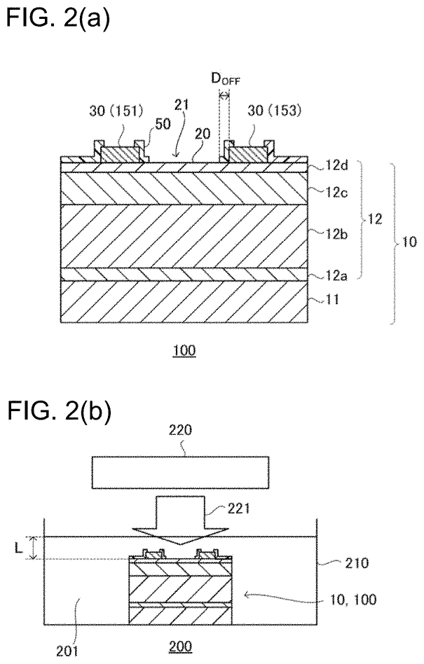

First, the recess forming step will be described. In the recess forming step, photoelectrochemical (PEC) etching is performed as the first etching to form the recess portion 110 on the epi layer 12. Here, the “recess portion 110” means a region of the epi layer 12 (a member composed of the Group III nitride) that has been subjected to PEC etching. FIG. 2(a) is a schematic cross-sectional view illustrating an object to be PEC-etched, that is, an object 100 (hereinafter, also referred to as a PEC object 100) to be immersed (contacted) in the etching solution 201 for PEC etching.

The PEC object 100 has a structure in which a mask 50 and a cathode pad 30 are provided on the epi layer 12 of the wafer 10. The PEC object 100 of this example is an embodiment in which the cathode pad 30 is used as (at least one of) the source electrode 151 and the drain electrode 153 of the HEMT, and specifically, for example, it has a structure in which the mask 50 for PEC etching is formed on a member at a stage where the source electrode 151 and the drain electrode 153 are formed on the surface 20 of the wafer 10.

The mask 50 is formed on the surface 20 of the epi layer 12, and has an opening in a region 21 (hereinafter, also referred to as a region 21 to be etched) in which the recess portion 110 should be formed, and has an opening for exposing the upper surface of the cathode pad 30 (source electrode 151 and drain electrode 153). The mask 50 is made of a non-conductive material such as resist, silicon oxide and the like.

The cathode pad 30 is a conductive member made of a conductive material, and is provided so as to be in contact with at least a part of the surface of a conductive region (of the epi layer 12) of the wafer 10 which is electrically connected to the region 21 to be etched.

FIG. 2(b) is a schematic cross-sectional view of the PEC etching apparatus 200 illustrating the recess forming step (that is, the PEC etching step). The PEC etching apparatus 200 includes a container 210 for accommodating an etching solution 201 and a light source 220 for emitting ultraviolet (UV) light 221.

In the recess forming step, the PEC object 100 is immersed in the etching solution 201, and the surface 20 of the epi layer 12 is irradiated with UV light 221 through the etching solution 201 in a state where the region 21 to be etched and the cathode pad 30 (at least a part of the cathode pad 30, for example, the upper surface) are in contact with the etching solution 201. In this way, the recess portion 110 is formed by etching the Group III nitride constituting the region 21 to be etched.

Here, a mechanism of the PEC etching will be described, and the etching solution 201, the cathode pad 30, and the like will be described in more detail. GaN will be described as an example of the Group III nitride to be etched.

As the etching solution 201 for PEC etching, alkaline or acidic etching solution 201 is used, containing oxygen used to generate oxides of group III elements contained in the Group III nitride that constitutes the region 21 to be etched (meaning the bottom 120 after the recess portion 110 have begun to be formed), and further containing an oxidizing agent that receives electrons.

As the oxidizing agent, peroxodisulfate ion (S₂O₈²⁻) is exemplified. Hereinafter, an embodiment of supplying S₂O₈²⁻ from potassium persulfate (K₂S₂O₈) will be exemplified. However, S₂O₈²⁻ may be supplied from others, for example, from sodium peroxodisulfate (Na₂S₂O₈), ammonium peroxodisulfate (ammonium persulfate, (NH₄)₂S₂O₈), or the like.

A first example of the etching solution 201 includes those in which potassium hydroxide (KOH) aqueous solution and potassium persulfate (K₂S₂O₈) aqueous solution are mixed and which show alkalinity at the start of PEC etching. Such an etching solution 201 is prepared, for example, by mixing 0.01 M KOH aqueous solution and 0.05 M K₂S₂O₈ aqueous solution at a ratio of 1:1. The concentration of the KOH aqueous solution, the concentration of the K₂S₂O₈ aqueous solution, and the mixing ratio of these aqueous solutions may be appropriately adjusted as necessary. The etching solution 201 in which the KOH aqueous solution and the K₂S₂O₈ aqueous solution are mixed can be made acidic at the start of PEC etching, for example, by lowering the concentration of the KOH aqueous solution.

A PEC etching mechanism when using the etching solution 201 of the first example will be described. By irradiating the surface 20 to be PEC-etched with UV light 221 having a wavelength of 365 nm or less, holes and electrons are generated as a pair in the GaN constituting the region 21 to be etched. The generated holes decompose GaN into Ga³⁺ and N₂ (Chemical formula 1), and further, Ga³⁺ is oxidized by hydroxide ions (OH⁻) to generate gallium oxide (Ga₂O₃) (Chemical formula 2). Then, the generated Ga₂O₃ is dissolved in an alkali (or acid). In this way, PEC etching of GaN is performed. The generated holes react with water and the water is decomposed to generate oxygen (Chemical formula 3).

GaN(s)+3h⁺→Ga³⁺+½N₂(g)↑ [Chemical formula 1]

Ga³⁺+3OH⁻→Ga₂O₃(s)+3/2H₂O(l) [Chemical formula 2]

H₂(l)+2h⁺→1/2O₂(g)↑+2H⁺ [Chemical formula 3]

Further, dissolution of K₂S₂O₈ in water produces peroxodisulfate ion (S₂O₈²⁻) (Chemical formula 4), and irradiation of S₂O₈²⁻ with UV light 221 produces sulfate ion radical (SO₄⁻* radical) (Chemical formula). 5). The electrons generated in pairs with the holes react with water together with SO₄⁻* radicals, and the water is decomposed to generate hydrogen (Chemical formula 6). In this way, in the PEC etching of the present embodiment, by using SO₄⁻* radicals, it is possible to consume the electrons generated in pairs with the holes in the GaN, and therefore the PEC etching can progress satisfactorily. As shown in (Chemical formula 6), as the sulfate ion (SO₄²⁻) increases with a progress of PEC etching, the acidity of the etching solution 201 becomes stronger (pH decreases).

K₂S₂O₈→2K⁺+S₂O₈²⁻ [Chemical formula 4]

S₂O₈²⁻+heat or hv+2SO₄⁻* [Chemical formula 5]

2SO₄⁻*+2e⁻+2H₂O(l)→2SO₄²⁻+2HO*+H₂(g)↑ [Chemical formula 6]

A second example of the etching solution 201 includes phosphoric acid (H₃PO₄) aqueous solution and potassium persulfate (K₂S₂O₈) aqueous solution which are mixed and show acidity at the start of PEC etching. Such an etching solution 201 is prepared, for example, by mixing a 0.01 M H₃PO₄ aqueous solution and a 0.05 M K₂S₂O₈ aqueous solution at a ratio of 1:1. The concentration of the H₃PO₄ aqueous solution, the concentration of the K₂S₂O₈ aqueous solution, and the mixing ratio of these aqueous solutions may be appropriately adjusted as necessary. Since both the H₃PO₄ aqueous solution and the K₂S₂O₈ aqueous solution are acidic, the etching solution 201 in which the H₃PO₄ aqueous solution and the K₂S₂O₈ aqueous solution are mixed, is acidic at an arbitrary mixing ratio. Since the K₂S₂O₈ aqueous solution itself is acidic, only the K₂S₂O₈ aqueous solution may be used as the etching solution 201 which is acidic at the start of etching. In this case, the concentration of the K₂S₂O₈ aqueous solution may be, for example, 0.025M.

It is preferable that the etching solution 201 is acidic from the start of PEC etching from a viewpoint of facilitating the use of a resist as the mask 50. This is because the resist mask is easily peeled off when the etching solution 201 is alkaline. When silicon oxide is used as the mask 50, there is no particular problem whether the etching solution 201 is acidic or alkaline.

As for a PEC etching mechanism when using the etching solution 201 of the second example, it is presumed that (chemical formula 1) to (chemical formula 3) described in the case of using the etching solution 201 of the first example are replaced with (chemical formula 7). That is, Ga₂O₃, hydrogen ions (H⁺), and N₂ are generated by a reaction of GaN, holes generated by irradiation with UV light 221 and water (Chemical formula 7). Then, the generated Ga₂O₃ is dissolved in the acid. In this way, PEC etching of GaN is performed. The mechanism of consuming the electrons generated in pairs with the holes, by S₂O₈² as shown in (Chemical formula 4) to (Chemical formula 6) is the same as in the case of using the etching solution 201 of the first example.

GaN(s)+3h⁺+3/2H₂O(l)→1/2Ga₂O₃(s)+3H⁺+1/2N₂(g)↑ [Chemical formula 7]

As understood from (Chemical formula 1) and (Chemical formula 2), or (Chemical formula 7), the region 21 to be etched (the bottom 120 of the recess portion 110) where PEC etching occurs, is considered to function as an anode in which the holes are consumed. Further, as understood from (Chemical formula 6), it is considered that the surface of the cathode pad 30, which is a conductive member electrically connected to the region 21 to be etched, in contact with the etching solution 201, functions as a cathode in which electrons are consumed (released).

(Particularly when the substrate 11 is semi-insulating (non-conductive)), and when the cathode pad 30 is not provided, it becomes difficult to secure a region that functions as a cathode, and the progress of the PEC etching becomes difficult. In the present embodiment, by providing the cathode pad 30, the PEC etching can progress satisfactorily. Further, by making the mask 50 have an opening on the upper surface of the cathode pad 30, that is, by allowing a large area on the upper surface of the cathode pad 30 to function as a cathode, the PEC etching can progress more satisfactorily.

As shown in (chemical formula 5), as a technique of generating SO₄* radicals from S₂O₈²⁻, at least one of the irradiation with UV light 221 and heating can be used. When using the irradiation with UV light 221, in order to increase a light absorption by S₂O₈²⁻ and efficiently generate SO₄⁻* radicals, it is preferable that a wavelength of the UV light 221 is 200 nm or more and less than 310 nm. That is, from a viewpoint of efficiently generating holes in the Group III nitride in the epi layer 12 and generating SO₄⁻* radicals from S₂O₈²⁻ in the etching solution 201 by irradiation with UV light 221, the wavelength of the UV light 221 is preferably 200 nm or more and less than 310 nm. When the generation of SO₄⁻* radicals from S₂O₈²⁻ is performed by heating, the wavelength of the UV light 221 may be 310 nm or more (at 365 nm or less).

When generating SO₄⁻* radicals from S₂O₈² by irradiation with UV light 221, a distance (wafer arrangement depth) L (see FIG. 2(b)) from the surface 20 of the wafer 10 to the upper surface of the etching solution 201 is preferably 1 mm or more and 100 mm or less, for example. When the distance L is excessively short, for example, less than 1 mm, an amount of SO₄⁻* radicals generated in the etching solution 201 above the wafer 10 may become unstable due to a fluctuation in the distance L. When the distance L is short, it becomes difficult to control a height of the liquid surface. Therefore, the distance L is preferably 1 mm or more, more preferably 3 mm or more, and further preferably 5 mm or more. Further, when the distance L is excessively long, for example, more than 100 mm, a large amount of SO₄⁻* radicals that do not contribute to PEC etching are unnecessarily generated in the etching solution 201 above the wafer 10, and therefore utilization efficiency of the etching solution 201 is reduced.

The present inventors found that when an edge of a mask used for PEC etching is made of a conductive material, the shape of the edge of the recess portion formed by PEC etching tends to be a disordered shape that does not follow the edge of the mask, and when the edge of the mask is made of a non-conductive material, it is easy to control the shape of the edge of the recess portion formed by PEC etching to the shape along the edge of the mask. Accordingly, it is preferable that a mask edge defining the region 21 to be etched (ie, the edge of the recess portion 110) is defined by the mask 50 made of a non-conductive material. Also, it is preferable that the cathode pad 30 is arranged (in a plan view) at a position away from the edge of the recess portion 110 (at a position that does not define the edge of the recess portion 110). Also, it is preferable that a distance DOFF (see FIG. 2(a)) between the edge of the mask 50 (in a plan view) and the edge of the cathode pad 30 is 5 μm or more, and more preferably 10 μm or more, from a viewpoint of satisfactorily controlling the shape of the edge of the recess portion 110.

PEC etching can also be performed to Group III nitrides other than the exemplified GaN. The group III element contained in the Group III nitride may be at least one of aluminum (Al), gallium (Ga) and indium (In). The concept of the PEC etching for the Al component or In component in the Group III nitride is the same as the concept described for the Ga component with reference to (Chemical formula 1) and (Chemical formula 2), or (Chemical formula 7). That is, the PEC etching can be performed by forming holes by irradiation with UV light 221 to generate an oxide of Al or an oxide of In, and dissolving these oxides in an alkali or an acid. The wavelength of the UV light 221 may be appropriately changed depending on the composition of the Group III nitride to be etched. When Al is contained, light having a shorter wavelength may be used, and when In is contained, light having a longer wavelength can also be used, with the PEC etching of GaN as a reference. That is, light having a wavelength for PEC-etching the Group III nitride, can be appropriately selected and used depending on the composition of the Group III nitride to be processed.

In the PEC object 100 of the present embodiment, the region 21 to be etched (the bottom 120 of the recess portion 110) which is an anode, and the cathode pad 30 which is a cathode, are conductive via 2DEG. Therefore, when the barrier layer 12c becomes thin as the PEC etching progresses and the 2DEG in the lower part of the recess portion 110 decreases, the PEC etching becomes difficult to progress, and eventually, the PEC etching can be automatically stopped with the barrier layer 12c having a predetermined thickness remaining in the lower part of the recess portion 110. The predetermined thickness can be adjusted by, for example, an intensity of the UV light 221. In this way, in the recess forming step, the formation of the recess portion 110 can be finished by automatically stopping the PEC etching.

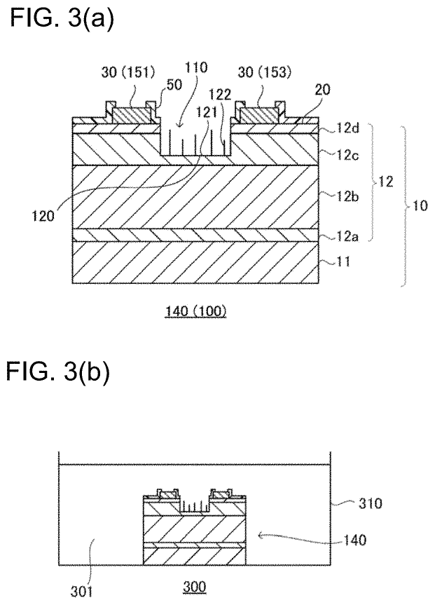

Next, the flattening step will be described. FIG. 3(a) is a schematic cross-sectional view of the PEC object 100, illustrating a state in which the recess forming step is finished. The PEC object 100 in which the recess portion 110 is formed in the recess forming step, becomes an object 140 to be flattened in the flattening step (hereinafter, also referred to as a flattening object 140).

As described above, dislocations are distributed at a predetermined density on the surface 20 of the epi layer 12. In the dislocations, a hole lifetime is short, so PEC etching is unlikely to occur. Therefore, a protruding portion 122 is likely to be formed as an undissolved portion of the PEC etching at a position corresponding to the dislocation on the bottom 120 of the recess portion 110. That is, in the recess forming step, a flat portion 121 (the portion where the PEC etching has progressed without dislocation) and a protruding portion 122 that is raised with respect to the flat portion 121 because the PEC etching is less likely to occur than the flat portion 121, are formed on the bottom 120 of the recess portion 110. Since the protruding portion 122 is the undissolved portion of the PEC etching, its height is at most a depth of the recess portion 110 or less.

In the flattening step, as described above, the bottom 120 of the recess portion 110 is flattened by performing a second etching (hereinafter, also referred to as flattening etching). Specifically, the protruding portion 122 is lowered by etching the protruding portion 122 (selectively with respect to the flat portion 121) by the flattening etching.

As the flattening etching, for example, wet etching using an acidic or alkaline etching solution (not PEC etching) is used. As an etching solution for the flattening etching, for example, hydrochloric acid (HCl) aqueous solution, mixed aqueous solution of hydrochloric acid (HCl) and hydrogen peroxide (H₂O₂) (hydrochloric acid hydrogen peroxide), mixed aqueous solution of sulfuric acid (H₂SO₄) and hydrogen peroxide (H₂O₂) (piranha solution), tetra hydroxide hydrochloric acid (TMAH) aqueous solution, hydrogen peroxide aqueous solution (sulfuric acid), potassium hydroxide (KOH) aqueous solution, etc., may be used.

The epi layer 12 heteroepitaxially grown on a substrate 11 which is a heterogeneous substrate such as a SiC substrate, a sapphire substrate, and a Si substrate, has a high dislocation density of, for example, 1×10⁸/cm² or more. Therefore, when using the substrate 11 which is a different type substrate, the flattening of the bottom 120 by the flattening step is particularly effective, because the protruding portion 122 is likely to be formed by the PEC etching in the recess forming step.

FIG. 3(b) is a schematic cross-sectional view of a flattening etching apparatus 300, illustrating a flattening step (that is, a flattening etching step). The flattening etching apparatus 300 has a container 310 for accommodating an etching solution 301. In the flattening etching step, the protruding portion 122 is etched by immersing a flattening object 140 in the etching solution 301 so that the recess portion 110 comes into contact with the etching solution 301. Thereby, the bottom 120 of the recess portion 110 is flattened. The flattening etching is not a PEC etching. Therefore, in the flattening step, the surface 20 of the epi layer 12 is not irradiated with UV light. Here, “not irradiated with UV light” means to prevent irradiation of (strong) UV light that causes unnecessary PEC etching.

It is known that it is difficult to etch the c-plane of Group III nitride such as GaN, but the PEC etching can etch the Group III nitride regardless of a crystal orientation, and therefore even the c-plane can be etched. The PEC etching in the recess forming step etches the Group III nitride constituting the epi layer 12 from a direction perpendicular to the surface 20 (that is, in a thickness direction of the epi layer 12) by irradiation with UV light 221 from above the surface 20 of the epi layer 12 which is the c-plane.

In contrast, the flattening etching is performed as normal wet etching, which is not PEC etching, using, for example, an etching solution such as hydrochloric acid hydrogen peroxide. In the normal wet etching, it is difficult to etch the c-plane of the Group III nitride, and therefore the flat portion 121 composed of the c-plane on the bottom 120 of the recess portion 110, is not etched. However, since the protruding portion 122 of the bottom 120 includes a crystal plane other than the c-plane, it can be etched by the normal etching. Accordingly, by the flattening etching, the protruding portion 122 can be selectively etched with respect to the flat portion 121. The flattening etching is to etch a crystal plane other than the c-plane, that is, a crystal plane intersecting the c-plane, so that the protruding portion 122 is etched from a direction that is not perpendicular to the c-plane (that is, in a direction that intersects the thickness direction of the epi layer 12 (lateral direction)).

By etching the protruding portion 122 by flattening etching, the protruding portion 122 can be lowered to bring the bottom 120 closer to flat, that is, the protruding portion 122 can be brought closer to the c-plane constituting the flat portion 121. When the protruding portion 122 is etched and close to the c-plane, the etching becomes difficult to progress. Therefore, in the flattening step of the present embodiment, it is easy to finish the flattening etching in a state where the protruding portion 122 is suppressed from being excessively etched and the bottom 120 is substantially flat.

After performing the flattening etching until the bottom 122 having a predetermined flatness is obtained, the flattening step is finished. A suitable flatness of the bottom 122 will be described later with reference to an experimental example.

The mask 50 used in the recess forming step may be removed in the flattening step, or may be removed by separately providing a mask removing step for removing the mask 50.

After the flattening step is finished, other steps for completing the HEMT 150 are performed (see FIG. 1 (a)). As other steps, a step of forming an element separation groove 160, a step of forming a gate electrode 152 on the bottom 120 of the recess portion 110, a step of forming a protective film 154, and the like are performed. In this way, the HEMT150 is manufactured.

An embodiment of the PEC object 100 (see FIG. 2(a)) in which the element separation groove 160 is not formed, that is, an embodiment in which the element separation groove 160 is formed after the recess forming step is exemplified, but by forming the element separation groove 160 before the recess forming step, the PEC object 100 with the element separation groove 160 formed therein, may be used.

The method for forming the element separation groove 160 is not particularly limited, and the element separation groove 160 may be formed by, for example, dry etching, or may be formed by, for example, PEC etching. When using the PEC etching, for example, by sufficiently increasing an intensity of the UV light to be irradiated, an etching depth is set so as to reach the middle of the channel layer 12b.

As described above, according to the present embodiment, the bottom 120 of the recess portion 110 formed by the PEC etching (first etching) in the recess forming step, can be flattened by the flattening etching (second etching) in the flattening step. Thereby, when the recess portion 110 is used as a recess in which the gate electrode 152 of the HEMT 150 is arranged, the characteristics of the HEMT 150 can be improved (for example, a leakage current can be reduced), compared with a case where the recess portion 110 is not flattened and the protruding portion 122 is present on the bottom 120.

Next, an experimental example relating to the PEC etching and flattening etching will be described. In this experimental example, a wafer having the following substrate and epi layer was used. The substrate was a semi-insulating SiC substrate. The epi layer has a laminated structure of a nucleation layer composed of AlN, a channel layer composed of GaN and having a thickness of 0.75 μm, a barrier layer composed of AlGaN (Al composition 0.22) and having a thickness of 24 nm, and a cap layer composed of GaN and having a thickness of 5 nm.

A recess portion was formed in the epi layer by PEC etching. The PEC etching was performed for 120 minutes using a 0.025 M K₂S₂O₈ aqueous solution as an etching solution and irradiating with UV light having a wavelength of 260 nm at an intensity of 3.8 mW/cm². A wafer placement depth L was 5 mm. The mask was made of silicon oxide and the cathode pad was made of titanium. A recess portion with a depth of 23.2 nm was formed. Since the thickness of the cap layer is 5 nm and the thickness of the barrier layer is 24 nm, the thickness of the barrier layer remaining under the recess portion is 5.8 nm.

After the PEC etching, the bottom of the recess portion was flattened by flattening etching. The flattening etching was performed for 10 minutes using hydrochloric acid hydrogen peroxide (for example, a mixture of 30% HCl and 30% H₂O₂ at a ratio of 1:1) as an etching solution.

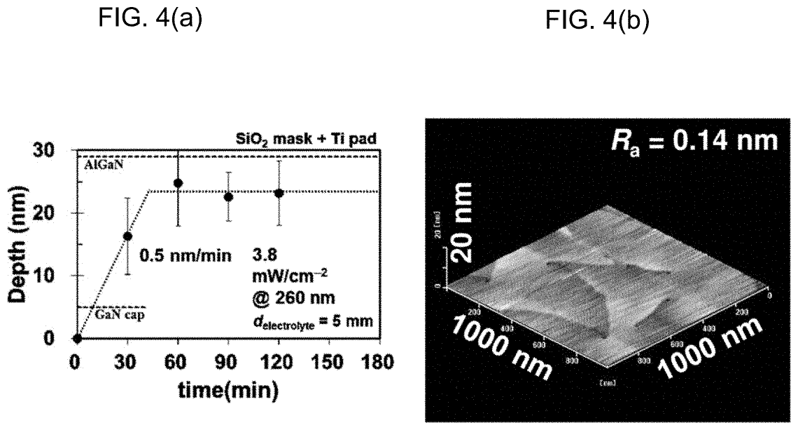

FIG. 4(a) is a graph showing a relationship between the etching time and an etching depth of the PEC etching. The horizontal axis shows the etching time, and the vertical axis shows the etching depth. From the start of etching to about 40 minutes, the etching depth becomes deeper in proportion to the etching time. About 40 minutes after the start of etching, the etching depth reaches 23.2 nm, and thereafter, the etching depth is constant. That is, the PEC etching is performed so that the etching is automatically stopped about 40 minutes after the start of etching.

A 1000 nm square region was observed using an atomic force microscope (AFM), for each of the surface of the epi layer before PEC etching (hereinafter referred to as an epi layer surface), the bottom of the recess portion formed by PEC etching and not flattened (hereinafter referred to as an unflattened bottom), and the bottom of the recess portion that has been flattened after PEC etching (hereinafter referred to as a flattened bottom).

FIG. 4(b) is an AFM image of the surface of the epi layer. Arithmetic mean roughness (Ra) obtained by AFM measurement on the surface of the epi layer is 0.14 nm. Since the epi layer is desired to have high crystallinity, Ra on the surface of the epi layer is preferably 0.4 nm or less, more preferably 0.3 nm or less, and further preferably 0.2 nm or less.

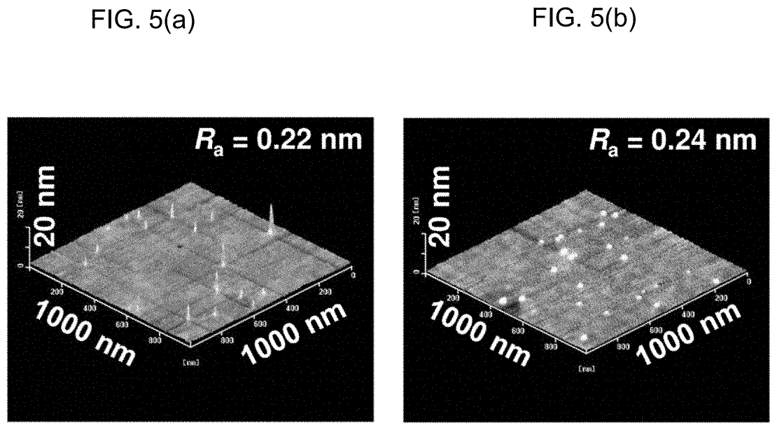

FIG. 5(a) is an AFM image of the unflattened bottom. On the unflattened bottom, a protruding portion is observed at a position corresponding to a dislocation. There is a tendency that the heights of the plurality of protruding portions distributed on the unflattened bottom, are not constant. The height of a maximum protruding portion exceeds 10 nm.

Ra obtained by AFM measurement on the unflattened bottom is 0.22 nm. Ra on the surface of the epi layer is, for example, 0.14 nm, while Ra on the unflattened bottom is, for example, 0.22 nm. Although the unflattened bottom has a protruding portion, its Ra is, for example, twice or less the Ra on the surface of the epi layer, and does not increase so much. It can be said that the reason for this is that the PEC etching was performed so that the flat portion, which occupies most of an area of the unflattened bottom, has high flatness, that is, so that the high flatness of the epi layer surface is almost not impaired in the flat portion. Ra of the unflattened bottom is preferably 0.4 nm or less, more preferably 0.3 nm or less.

FIG. 5(b) is an AFM image of the flattened bottom. In the flattened bottom, the protruding portion observed in the unflattened bottom is not clearly observed, and it is found that the bottom of the protruding portion is flattened. On the flattened bottom, a position where the protruding portion is presumed to have been formed, that is, a position corresponding to the dislocation, is observed as a bright region separately from the flat portion. The bright region is not observed in a clear protruding shape, but is observed in a substantially flat shape (at a height almost equal to that of the flat portion). However, for convenience of explanation below, the bright region is referred to as a protruding portion in some cases.

Ra obtained by AFM measurement on the flattened bottom is 0.24 nm. Ra of the unflattened bottom is, for example, 0.22 nm, while Ra of the flattened bottom is slightly larger, for example, 0.24 nm, and this difference is considered to be an error due to a difference between a measurement area of the unflattened bottom and a measurement area of the flattened bottom, and Ra of the unflattened bottom and Ra of the flattened bottom are considered to be about the same. It can be said that it is difficult to clearly distinguish between the unflattened bottom and the flattened bottom only by Ra. From the AFM image of the flattened bottom, it is found that the protruding portion can be selectively etched by the flattening etching without deteriorating the flatness of the flat portion.

A preferable flatness of the flattened bottom can be expressed as follows. For example, in the flattened bottom, the height of the maximum protruding portion among the plurality of distributed protruding portions is 1/10 or less of the depth of the recess portion. Also, for example, in the flattened bottom, the height of the maximum protruding portion among the plurality of distributed protruding portions is preferably 2 nm or less, more preferably 1 nm or less (the maximum height of the position corresponding to the dislocation is preferably 2 nm or less, and more preferably 1 nm or less). Also, for example, Ra of the flattened bottom is preferably 0.4 nm or less, more preferably 0.3 nm or less.

As described above, according to the present embodiment, the feature of the epi layer surface can be said to be the feature observed for the surface 20 of the epi layer 12 before the recess forming step (or a feature observed for the surface 20 of the epi layer 12 where the PEC etching is not applied, outside of the recess portion 110 after the recess forming step or the flattening step). Further, as described above, according to the present embodiment, the feature of the unflattened bottom can be said to be the feature observed for the bottom 120 of the recess portion 110 after the recess forming step and before the flattening step. Further, as described above, according to the present embodiment, the feature of the flattened bottom can be said to be the feature observed for the bottom 120 of the recess portion 110 after the flattening step. Also, according to the present embodiment, the feature observed for the bottom 120 of the recess portion 110 after the flattening step can be said to be the feature of the HEMT 150.

In the bottom 120 of the recess portion 110 formed by PEC etching, there is less damage to the Group III nitride crystal (as compared to, for example, dry etching) due to the etching to form the recess portion 110.

Further, in the bottom 120 of the recess portion 110 formed by PEC etching, halogen element residue is less than that in the case of forming the recess portion 110 by dry etching. When trying to form the recess portion 110 by dry etching, an etching gas containing a halogen element is made to collide with the bottom 120 or a reaction for halogenating the bottom 120 is used, and therefore the halogen element remains in the bottom 120 (inside the surface layer portion having a predetermined thickness) of the recess portion 110. Compared to such dry etching, the PEC etching and the flattening etching in the present embodiment can be performed as wet etching so that the halogen element does not remain in the bottom 120 (inside of the surface layer portion having a predetermined thickness) of the recess portion 110. The concentration of the halogen element (eg, chlorine (Cl)) in the bottom 120 of the recess portion 110 is preferably less than 1×10¹⁵/cm³, more preferably less than 5×10¹⁴/cm³, and even more preferably less than 2×10¹⁴/cm³.

### First Modified Example

Next, a first modified example of the above-described embodiment will be described. The above-described embodiment is an embodiment in which wet etching (not PEC etching) using an acidic or alkaline etching solution is used as the flattening etching, that is, an embodiment in which the protruding portion 122 is chemically etched. A mechanism of the flattening etching is not particularly limited as long as the protruding portion 122 is etched so that the bottom 120 is flattened. Therefore, the flattening etching may be performed by etching of a mechanism other than chemical etching. By combining etchings of a plurality of mechanisms, the flattening etching may be performed more effectively.

The flattening etching may be performed, for example, by mechanically removing the protruding portion 122, for example, bubbling cleaning may be used, or, for example, scrub cleaning may be used as the mechanical flattening etching. Examples of the etching solution (cleaning solution) for bubbling cleaning include hydrochloric acid hydrogen peroxide exemplified in the above-described embodiment. When the protruding portion 122 is etched with hydrogen peroxide, bubbles are violently generated. Therefore, the protruding portion 122 can be destroyed and removed by an impact caused by the generation of the bubbles. Hydrochloric acid hydrogen peroxide can be said to be an etching solution that chemically and mechanically etches the protruding portion 122.

### Second Modified Example

Next, a second modified example of the above-described embodiment will be described. The above-described embodiment is an embodiment in which the PEC etching for forming the recess portion 110 is finished and then the flattening etching for flattening the bottom 120 of the recess portion 110 is performed.

This modified example is an embodiment in which the flattening etching is performed before finishing the PEC etching for forming the recess portion 110, that is, performed at a stage where the recess portion 110 is formed to a depth in the middle, then, the PEC etching is performed again to make the recess portion 110 deeper. That is, this modified example is an embodiment in which the recess forming step and the flattening step are alternately repeated. The flattening step may be performed a plurality of times as needed. In the same manner as in the above-described embodiment, the flattening step may be performed after formation of the recess portion 110 is finished.

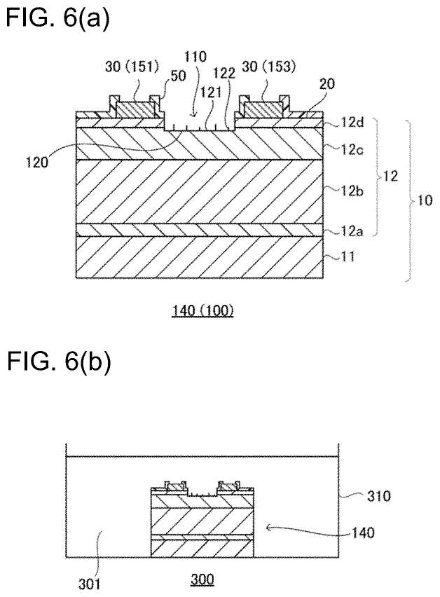

FIG. 6(a) is a schematic cross-sectional view illustrating the flattening object 140 in this modified example. FIG. 6(b) is a schematic cross-sectional view of the flattening etching apparatus 300, illustrating the flattening step of this modified example. The flattening etching apparatus 300 is the same as that of the above-described embodiment.

The recess portion 110 illustrated in FIG. 6(a) is in a state of being formed to a depth in the middle. Since the protruding portion 122 is an undissolved portion of the PEC etching, the protruding portion 122 formed in this modified example in which the recess portion 110 is shallow, is generally low, and a difference in height between the protruding portions 122 is small, compared to the protruding portion 122 (see FIG. 3(a)) formed in the above-described embodiment in which the recess portion 110 is deep.

Therefore in the flattening step (per time) of this modified example, it becomes easy to etch the protruding portion 122, and it becomes easy to make the height of the protruding portion 122 after etching uniform. Then, by repeating the flattening step a plurality of times, the protruding portion 122 can be etched more reliably. Thereby, according to this modified example, the flatness of the bottom 120 of the recess portion 110 can be further improved.

### Third Modified Example

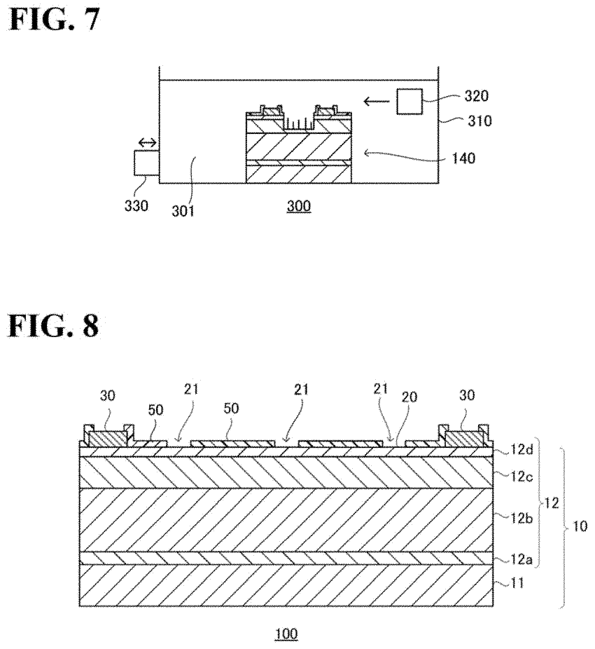

Next, a third modified example of the above-described embodiment will be described. In this modified example, the flattening etching apparatus 300 is different from that of the above-described embodiment. FIG. 7 is a schematic cross-sectional view of the flattening etching apparatus 300 according to the third modified example.

The flattening etching apparatus 300 of this modified example has a configuration in which a flow generation mechanism 320 and a vibration generation mechanism 330 are added to the flattening etching apparatus 300 according to the above-described embodiment. The flow generation mechanism 320 causes the etching solution 301 to generate a flow (movement). The vibration generation mechanism 330 is, for example, an ultrasonic generator, and gives vibration to the etching solution 301. In this modified example, by generating a flow (movement) in the etching solution 301 and by giving vibration to the etching solution 301, that is, by performing at least one of them, it becomes possible to enhance an action of mechanically etching the protruding portion 122.

### OTHER EMBODIMENTS

The embodiment of the present invention has been specifically described above. However, the present invention is not limited to the above-described embodiment, and various changes, improvements, combinations, and the like can be made without departing from the gist thereof.

For example, the above-described embodiment is the embodiment in which the cathode pad 30 is used as at least one of the source electrode 151 and the drain electrode 153 of the HEMT 150. However, the cathode pad 30 may be a conductive member different from the source electrode 151 or the drain electrode 153 of the HEMT 150.

FIG. 8 is a schematic cross-sectional view of the PEC object 100 illustrating such other embodiment. In this embodiment, a conductive member having a different arrangement and shape from the source electrode 151 or the drain electrode 153, may be used as the cathode pad 30. The cathode pad 30 is arranged in an annular shape along an outer circumference of the wafer 10, for example. The arrangement, shape, size, number, etc. of the cathode pad 30 may be variously adjusted as needed. The mask 50 has an opening in the region 21 to be etched to form the recess portion (recess where the gate electrode 152 is arranged) 110 of each HEMT element, and also has an opening that exposes the upper surface of the cathode pad 30.

In this embodiment, the cathode pad 30 may not be provided for each HEMT element, and the cathode pad 30 arranged outside of a certain HEMT element (outside of the element separation groove 160 that surrounds this HEMT element in a plan view) may be used to form the recess portion 110 of the HEMT element. As described above, at the time of the PEC etching, it is preferable that the region 21 to be etched (the bottom 120 of the recess portion 110) is conducting with the cathode pad 30 via 2DEG. Therefore, in such an embodiment, it is preferable to provide the element separation groove 160 for separating the 2DEGs of each HEMT element, after finish of the PEC etching.

After the PEC etching is finished, that is, after the recess forming step is finished, the cathode pad 30 is removed. The cathode pad 30 may be removed after the recess forming step is finished, before the flattening step, after the flattening step, or may be removed in the flattening step. In this embodiment, after the recess forming step is finished, the source electrode 151 and the drain electrode 153 of each HEMT element are formed as a conductive member separate from the cathode pad 30 (see FIG. 1(a)).

In the above description, although the completed HEMT was referred to as the structure 150, the structure 150 may be a member having at least the epi layer 12 including the recess portion 110 formed by the recess forming step and the flattening step described above.

### Preferable Aspects of the Present Invention

Hereinafter, preferable aspects of the present invention will be supplementarily described.

### (Supplementary Description 1)

There is provided a method for manufacturing a structure, including:

forming a recess portion by performing a first etching to a surface of a member composed of Group III nitride; and

flattening a bottom of the recess portion by performing a second etching to the bottom,

wherein in forming the recess portion, a flat portion and a protruding portion are formed on the bottom of the recess portion, the protruding portion being raised with respect to the flat portion because it is less likely to be etched by the first etching than the flat portion, and

in flattening the bottom, by etching the protruding portion (selectively for the flat portion) by the second etching, the protruding portion is lowered.

### (Supplementary Description 2)

There is provided the method for manufacturing a structure according to the supplementary description 1, wherein the protruding portion is formed at a position corresponding to a dislocation of the Group III nitride constituting the member.

### (Supplementary Description 3)

There is provided the method for manufacturing a structure according to the supplementary description 1 or 2, wherein the surface is composed of a c-plane of the Group III nitride, and the Group III nitride is etched from a direction perpendicular to the surface in the first etching, and the protruding portion is etched from a direction that is not perpendicular to the c-plane in the second etching.

### (Supplementary Description 4)

There is provided the method for manufacturing a structure according to the supplementary description 3, wherein the first etching is photoelectrochemical etching.

### (Supplementary Description 5)

There is provided the method for manufacturing a structure according to the supplementary description 3 or 4, wherein the second etching is wet etching using an acidic or alkaline etching solution (rather than photoelectrochemical etching).

### (Supplementary Description 6)

There is provided the method for manufacturing a structure according to any one of the supplementary descriptions 1 to 5, wherein the Group III nitride is etched from a direction perpendicular to the surface in the first etching, and the protruding portion is mechanically removed in the second etching.

### (Supplementary Description 7)

There is provided the method for manufacturing a structure according to the supplementary description 6, wherein the first etching is photoelectrochemical etching.

### (Supplementary Description 8)

There is provided the method for manufacturing a structure according to the supplementary description 6 or 7, wherein the second etching is bubbling cleaning.

### (Supplementary Description 9)

There is provided the method for manufacturing a structure according to any one of the supplementary descriptions 6 to 8, wherein the second etching is scrubbing.

### (Supplementary Description 10)

There is provided the method for manufacturing a structure according to any one of the supplementary descriptions 1 to 9, wherein the first etching is photoelectrochemical etching in which by irradiating the surface with ultraviolet light from above, the Group III nitride is etched from a direction perpendicular to the surface.

### (Supplementary Description 11)

There is provided the method for manufacturing a structure according to any one of the supplementary descriptions 1 to 10, wherein the surface is not irradiated with ultraviolet light (that causes photoelectrochemical etching) in the second etching.

### (Supplementary Description 12)

There is provided the method for manufacturing a structure according to any one of the supplementary descriptions 1 to 11, wherein a maximum height of the protruding portion is 1/10 or less of a depth of the recess portion, which is measured by observing a 1000 nm square region of the bottom using an AFM after flattening the bottom.

### (Supplementary Description 13)

There is provided the method for manufacturing a structure according to any one of the supplementary descriptions 1 to 12, wherein a maximum height of the protruding portion is preferably 2 nm or less, more preferably 1 nm or less, which is measured by observing a 1000 nm square region of the bottom using an AFM after flattening the bottom.

### (Supplementary Description 14)

There is provided the method for manufacturing a structure according to any one of the supplementary descriptions 1 to 13, wherein an arithmetic mean roughness (Ra) of the bottom is preferably 0.4 nm or less, more preferably 0.3 nm or less, which is measured by observing a 1000 nm square region of the bottom using an AFM after flattening the bottom.

### (Supplementary Description 15)

There is provided the method for manufacturing a structure according to any one of the supplementary descriptions 1 to 14, wherein the protruding portion is selectively etched with respect to the flat portion in the second etching in flattening the bottom.

### (Supplementary Description 16)

There is provided the method for manufacturing a structure according to any one of the supplementary descriptions 1 to 15, wherein an arithmetic mean roughness (Ra) of the bottom is preferably 0.4 nm or less, more preferably 0.3 nm or less, which is measured by observing a 1000 nm square region of the bottom using an AFM after forming the recess portion and before flattening the bottom.

### (Supplementary Description 17)

There is provided the method for manufacturing a structure according to any one of the supplementary descriptions 1 to 16, wherein an arithmetic mean roughness (Ra) of the surface is preferably 0.4 nm or less, more preferably 0.3 nm or less, still more preferably 0.2 nm or less, which is measured by observing the surface using an AFM, before forming the recess portion.

### (Supplementary Description 18)

There is provided the method for manufacturing a structure according to any one of the supplementary descriptions 1 to 17,

wherein the structure is used as a high electron mobility transistor, the method including:

forming a gate electrode of the high electron mobility transistor on the bottom, after flattening the bottom.

### (Supplementary Description 19)

There is provided the method for manufacturing a structure according to any one of the supplementary descriptions 1 to 18, wherein the first etching is photoelectrochemical etching, and an etching solution for the photoelectrochemical etching is an alkaline or acidic etching solution containing an oxidizing agent that receives electrons.

### (Supplementary Description 20)

There is provided the method for manufacturing a structure according to any one of the supplementary descriptions 1 to 19, wherein the first etching is photoelectrochemical etching,

the photoelectrochemical etching is performed in forming the recess portion, with a mask placed on the surface,

an etching solution for the photoelectrochemical etching is an acidic etching solution (from a start of the first etching), and the mask is a resist mask.

### (Supplementary Description 21)

There is provided the method for manufacturing a structure according to any one of the supplementary descriptions 1 to 20, wherein the first etching is photoelectrochemical etching,

the photoelectrochemical etching is performed in forming the recess portion, with a mask and a conductive member arranged on the surface,

the mask is made of a non-conductive material, defining an edge of the recess portion, and

the conductive member is arranged at a position away from the edge of the recess portion (at a position that does not define the edge of the recess portion), and at least a part (upper surface) of the conductive member is arranged so as to be in contact with an etching solution of the photoelectrochemical etching.

### (Supplementary Description 22)

There is provided the method for manufacturing a structure according to the supplementary description 21, wherein the structure is used as a high electron mobility transistor, the recess portion is used as a recess in which a gate electrode of the high electron mobility transistor is arranged, and the conductive member is used as at least one of a source electrode and a drain electrode of the high electron mobility transistor.

### (Supplementary Description 23)

There is provided the method for manufacturing a structure according to the supplementary description 21, wherein

the structure is used as a high electron mobility transistor, the recess portion is used as a recess in which the gate electrode of the high electron mobility transistor is arranged, and

after forming the recess portion, a source electrode and a drain electrode of the high electron mobility transistor are formed as a conductive member different from the above conductive member.

### (Supplementary Description 24)

There is provided the method for manufacturing a structure according to the supplementary description 23, wherein an element separation groove of the high electron mobility transistor is formed after forming the recess portion.

### (Supplementary Description 25)

There is provided the method for manufacturing a structure according to any one of the supplementary descriptions 1 to 24, wherein forming the recess portion and flattening the bottom is repeated alternately.

### (Supplementary Description 26)

There is provided the method for manufacturing a structure according to any one of the supplementary descriptions 1 to 25, wherein the second etching is performed while generating a flow (movement) in an etching solution used for the second etching.

### (Supplementary Description 27)

There is provided the method for manufacturing a structure according to any one of the supplementary descriptions 1 to 26, wherein the second etching is performed while applying vibration to an etching solution used for the second etching.

### (Supplementary Description 28)

There is provided a structure having a member, which is composed of Group III nitride and has a recess portion,

in which a maximum height at a position corresponding to a dislocation of the Group III nitride constituting the member is preferably 2 nm or less, more preferably 1 nm or less, which is measured by observing a 1000 nm square region at a bottom of the recess portion using AFM, and

an arithmetic mean roughness (Ra) of the bottom measured by observing using the AFM is preferably 0.4 nm or less, more preferably 0.3 nm or less.

### (Supplementary Description 29)

There is provided the structure according to the supplementary description 28, wherein the member has a surface composed of a c-plane of the Group III nitride, and the recess portion is formed on the surface.

### (Supplementary Description 30)

There is provided the structure according to the supplementary description 28 or 29, having a substrate, wherein the member is composed of the Group III nitride grown heteroepitaxially on the substrate.

### (Supplementary Description 31)

There is provided the structure according to any one of the supplementary descriptions 28 to 30, wherein in a bottom of the recess portion, a concentration of a halogen element (eg, chlorine) is preferably less than 1×10¹⁵/cm³, more preferably less than 5×10¹⁴/cm³, still more preferably less than 3×10¹⁴/cm³.

### (Supplementary Description 32)

There is provided the structure according to any one of the supplementary descriptions 28 to 31, used as a high electron mobility transistor, wherein the recess portion is used as a recess in which a gate electrode of the high electron mobility transistor is arranged.

### (Supplementary Description 33)

There is provided a method for manufacturing a structure, including:

performing photoelectrochemical etching to a region to be etched of a member composed of Group III nitride and used as a high electron mobility transistor; and

forming an element separation region of the high electron mobility transistor in the member,

wherein in performing the photoelectrochemical etching, the photoelectrochemical etching is performed to the region to be etched, using a conductive member that is arranged outside of a region where the element separation region should be formed and conducts with the region to be etched via a two-dimensional electron gas, and

the formation of the element separation region is performed after performing the photoelectrochemical etching.

### (Supplementary Description 34)

There is provided the method for manufacturing a structure according to the supplementary description 33, wherein the region to be etched is a region where a recess portion is formed in which a gate electrode of the high electron mobility transistor is arranged.

### (Supplementary Description 35)

There is provided the method for manufacturing a structure according to the supplementary description 33 or 34, wherein in performing the photoelectrochemical etching, the photoelectrochemical etching is performed using a mask made of a non-conductive material and having an opening in the region to be etched and an opening for exposing the conductive member.

### (Supplementary Description 36)

There is provided the method for manufacturing a structure according to any one of the supplementary descriptions 33 to 35, wherein after performing the photoelectrochemical etching, the conductive member is removed to form a source electrode and a drain electrode of the high electron mobility transistor.

### DESCRIPTION OF SIGNS AND NUMERALS

10 . . . wafer, 11 . . . substrate, 12 . . . epi layer, 20 . . . surface (of epi layer), 21 . . . region to be etched, 30 . . . cathode pad, 50 . . . mask, 100 . . . PEC object, 110 . . . recess portion, 120 . . . bottom, 121 . . . flat part, 122 . . . protruding portion, 140 . . . flattening object, 150 . . . structure, 151 . . . source electrode, 152 . . . gate electrode, 153 . . . drain electrode, 160 . . . element separation groove, 200 . . . PEC etching apparatus, 201 . . . etching liquid, 210 . . . container, 220 . . . light source, 221 . . . UV light, 300 . . . flattening etching device, 301 . . . etching liquid, 310 . . . container, 320 . . . flow generation mechanism, 330 . . . vibration generation mechanism

1. A method for manufacturing a structure, comprising:
forming a recess portion by performing a first etching to a surface of a member composed of Group III nitride; and
flattening a bottom of the recess portion by performing a second etching to the bottom,
wherein in forming the recess portion, a flat portion and a protruding portion are formed on the bottom of the recess portion, the protruding portion being raised with respect to the flat portion because it is less likely to be etched by the first etching than the flat portion, and
in flattening the bottom, by etching the protruding portion by the second etching, the protruding portion is lowered.

2. The method for manufacturing a structure according to claim 1, wherein the protruding portion is formed at a position corresponding to a dislocation of the Group III nitride constituting the member.

3. The method for manufacturing a structure according to claim 1, wherein the surface is composed of a c-plane of the Group III nitride, and the Group III nitride is etched from a direction perpendicular to the surface in the first etching, and the protruding portion is etched from a direction that is not perpendicular to the c-plane in the second etching.

4. The method for manufacturing a structure according to claim 3, wherein the first etching is photoelectrochemical etching.

5. The method for manufacturing a structure according to claim 3, wherein the second etching is wet etching using an acidic or alkaline etching solution.

6. The method for manufacturing a structure according to claim 1, wherein the Group III nitride is etched from a direction perpendicular to the surface in the first etching, and the protruding portion is mechanically removed in the second etching.

7. The method for manufacturing a structure according to claim 6, wherein the first etching is photoelectrochemical etching.

8. The method for manufacturing a structure according to claim 6, wherein the second etching is bubbling cleaning.

9. The method for manufacturing a structure according to claim 6, wherein the second etching is scrubbing.

10. The method for manufacturing a structure according to claim 1, wherein a maximum height of the protruding portion is 1/10 or less of a depth of the recess portion, which is measured by observing a 1000 nm square region of the bottom using an AFM after flattening the bottom.

11-12. (canceled)

13. The method for manufacturing a structure according to claim 1, wherein the protruding portion is selectively etched with respect to the flat portion in the second etching in flattening the bottom.

14. (canceled)

15. The method for manufacturing a structure according to claim 1,
wherein the structure is used as a high electron mobility transistor, the method including:
forming a gate electrode of the high electron mobility transistor on the bottom, after flattening the bottom.

16-17. (canceled)

18. The method for manufacturing a structure according to claim 1,
wherein the first etching is photoelectrochemical etching,
the photoelectrochemical etching is performed in forming the recess portion, with a mask and a conductive member arranged on the surface,
the mask is made of a non-conductive material, defining an edge of the recess portion, and
the conductive member is arranged at a position away from the edge of the recess portion, and at least a part of the conductive member is arranged so as to be in contact with an etching solution of the photoelectrochemical etching; and
wherein the structure is used as a high electron mobility transistor, the recess portion is used as a recess in which a gate electrode of the high electron mobility transistor is arranged, and the conductive member is used as at least one of a source electrode and a drain electrode of the high electron mobility transistor.

19. The method for manufacturing a structure according to claim 1, wherein forming the recess portion and flattening the bottom is repeated alternately.

20. A structure having a member, which is composed of Group III nitride and has a recess portion,
in which a maximum height at a position corresponding to a dislocation of the Group III nitride constituting the member is 2 nm or less, which is measured by observing a 1000 nm square region at a bottom of the recess portion using AFM, and
an arithmetic mean roughness (Ra) of the bottom measured by observing using the AFM is 0.4 nm or less.

21. The structure according to claim 20, used as a high electron mobility transistor, wherein the recess portion is used as a recess in which a gate electrode of the high electron mobility transistor is arranged.

22. A method for manufacturing a structure, comprising:
performing photoelectrochemical etching to a region to be etched of a member composed of Group III nitride and used as a high electron mobility transistor; and
forming an element separation region of the high electron mobility transistor in the member,
wherein in performing the photoelectrochemical etching, the photoelectrochemical etching is performed to the region to be etched, using a conductive member that is arranged outside of a region where the element separation region should be formed and conducts with the region to be etched via a two-dimensional electron gas, and
the formation of the element separation region is performed after performing the photoelectrochemical etching.

23. The method for manufacturing a structure according to claim 22,
wherein the region to be etched is a region where a recess portion is formed in which a gate electrode of the high electron mobility transistor is arranged.

24. The method for manufacturing a structure according to claim 22, wherein in performing the photoelectrochemical etching, the photoelectrochemical etching is performed using a mask made of a non-conductive material and having an opening in the region to be etched and an opening for exposing the conductive member.

25. The method for manufacturing a structure according to claim 22, wherein after performing the photoelectrochemical etching, the conductive member is removed, and a source electrode and a drain electrode of the high electron mobility transistor are formed.
